(19) United States
(12) Patent Application Publication
(10) Pub. No.: US 2021/0218436 A1
(43) Pub. Date: Jul. 15, 2021

(54) RESONANCE FREE TRANSMISSION SYSTEM

(71) Applicant: ACCELINK USA CORPORATION, Fremont, CA (US)

(72) Inventors: Yunpeng Song, Fremont, CA (US); Rong Huang, Fremont, CA (US)

(73) Assignee: ACCELINK USA CORPORATION, Fremont, CA (US)

(21) Appl. No.: 16/742,915

(22) Filed: Jan. 15, 2020

(51) Int. Cl. H04B 1/58; H01R 13/6471

(52) U.S. Cl. CPC H04B 1/583; H01R 13/6471

(57) ABSTRACT

The present invention describes a transmission system for removing resonance and improves performance by utilizing air bridges connecting ground lines in a G-S-S-G transmission line configuration.

### BACKGROUND OF THE INVENTION

This application relates to the field of signal propagation. In particular, the present invention relates to transmission line configurations for signal propagation in telecommunication devices.

This application also relates to differential signaling that relates to a particular application of this general concept. Specifically, two signals are sent from one device as outputs. These two signals are received by a second device as inputs. The information contained within the signals is derived from the differences in voltage or current between them by the second device. This allows various external noise signals to be subtracted out when the inputs are processed. The differences in signals convey the information rather than one signal evaluated with respect to a ground. When transmitting at very high data rates, over long distances and through noisy environments, single-ended transmission is often inadequate. In these applications, differential data transmission offers superior performance.

The disadvantages of differential signaling result from the additional space, design complexity, and production costs association with increasing the number of pins, traces and transceivers. In addition, therefore, it is desirable to have systems and methods to enable self-calibration for the cameras to save time and efforts.

### SUMMARY OF THE INVENTION

In one aspect, the invention relates to a signal transmission structure for differential transmission lines including first, second ground structures and first and second signal lines. The width of the first signal line and the separation between the first signal line and each of the first and second ground structures are sufficient to permit fabrication of a circuit element on the first signal line in some embodiments. In another aspect, the invention relates to providing complementary decoupled differential transmission line connections between signal transmission lines and optical-electronic receivers and de-multiplexing devices. In another aspect, the invention relates to connecting communication devices with an electrical ground (G) and signal (S) connections arranged in a G-S-S-G configuration.

In one aspect, the invention relates to differential transmission lines. The structure includes a first ground structure, a first signal line, a second signal line and a second ground structure. The first signal line is typically positioned adjacent and substantially parallel to the first ground structure. The second signal line has a first separation distance from the first signal line and is typically positioned adjacent and substantially parallel to the first signal line. The second ground structure typically has a second separation distance from the second signal line and is positioned adjacent and substantially parallel to the second signal line. The first and the second signal lines are typically positioned between both the first and the second ground structures. Therefore, the invention relates to connecting communication devices with an electrical ground (G) and signal (S) connections arranged in a G-S-S-G configuration.

In some embodiments, The invention relates to a signal transmission system, comprising: A substrate; a first ground line mounted on the substrate, wherein the first ground line is coupled to ground potential; a second ground line mounted on the substrate, wherein the second ground line is coupled to the ground potential, wherein the second ground line is approximately parallel to the first ground line, wherein there are a certain distance between the first ground line and the second ground line; a number of gold lines coupled to both the first ground line and the second ground line, wherein the number of gold lines forms bridges between the first ground line and the second ground line; and a pair of signal lines mounted on the substrate, wherein the pair of signal lines are in-between of the first ground line and the second ground line, wherein the pair of signal lines transmit signals, wherein the bridges formed by the number of gold lines are configured to remove resonance and improve high frequency performance of signal transmission. In some embodiments, the signals are transmitted via optical means. In some embodiments, the signals are transmitted via electrical means. In some embodiments, the resonance is harmful for the signal transmission system. In some embodiments, frequency of the signal transmission system is configured to reach 35 Ghz. In some embodiments, the resonance occurs more than three times.

In some embodiments, the invention relates to a method of transmitting signals, comprising: mounting a first ground line on a substrate, wherein the first ground line is coupled to ground potential; mounting a second ground line on the substrate, wherein the second ground line is coupled to the ground potential, wherein the second ground line is approximately parallel to the first ground line, wherein there are a certain distance between the first ground line and the second ground line; attaching a number of gold lines both the first ground line and the second ground line, wherein the number of gold lines forms bridges between the first ground line and the second ground line; mounting a pair of signal lines on the substrate, wherein the pair of signal lines are in-between of the first ground line and the second ground line, wherein the pair of signal lines transmit signals, wherein the bridges formed by the number of gold lines are configured to remove resonance and improve high frequency performance of signal transmission. In some embodiments, the signals are transmitted via optical means. In some embodiments, the signals are transmitted via electrical means. In some embodiments, the resonance is harmful for the signal transmission system. In some embodiments, frequency of the signal transmission system is configured to reach 35 Ghz. In some embodiments, the resonance occurs more than three times before being removed by air bridges.

These and other aspects, their implementations and other features are described in details in the drawings, the description and the claims.

### BRIEF DESCRIPTION OF THE DRAWINGS

FIG. 1 shows an example of a transmission system with G-S-S-G structure and air bridges connecting ground lines at one cross section

FIG. 2 shows an example of a transmission system with G-S-S-G structure and air bridges connecting ground lines at another cross section

FIG. 3 shows an example of a method with G-S-S-G structure and air bridges

### DETAILED DESCRIPTION OF THE INVENTION

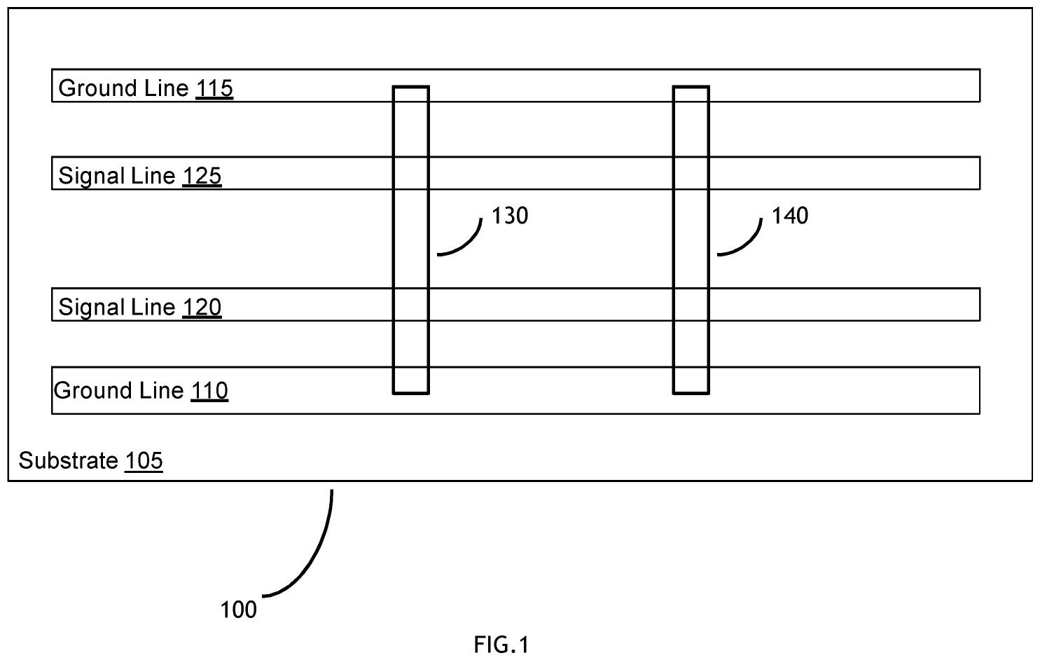

FIG. 1 shows an example of a transmission system 100 with G-S-S-G structure and air bridges connecting ground lines at one cross section.

In some embodiments, the system 100 comprises a substrate 105.

In some embodiments, the system 100 comprises a first ground line 110 mounted on the substrate 105, wherein the first ground line 110 is coupled to ground potential.

In some embodiments, the system 100 comprises a second ground line 115 mounted on the substrate 105, wherein the second ground line 115 is coupled to the ground potential, wherein the second ground line 115 is approximately parallel to the first ground line 110, wherein there are a certain distance between the first ground line 110 and the second ground line 115; a number of gold lines 130 and 140 coupled to both the first ground line 110 and the second ground line 115. In some embodiments, gold lines 130 and 140 forms bridges between the first ground line 110 and the second ground line 115.

In some embodiments, the system 100 comprises a pair of signal lines 120 and 125 mounted on the substrate 105, wherein the pair of signal lines 120 and 125 are in-between of the first ground line 110 and the second ground line 115, wherein the pair of signal lines 120 and 125 transmit signals, wherein the bridges formed by the number of gold lines 130 and 140 are configured to remove resonance and improve high frequency performance of signal transmission. In some embodiments, the signals are transmitted via optical means. In some embodiments, the signals are transmitted via electrical means. In some embodiments, the resonance is harmful for the signal transmission system. In some embodiments, frequency of the signal transmission system is configured to reach 35 Ghz. In some embodiments, the resonance occurs more than three times. In some embodiments, only one gold line exists. In some embodiments, more than two gold lines exist. In some embodiments, the gold line 130 and 140 are not connected to signal lines 120 and 125.

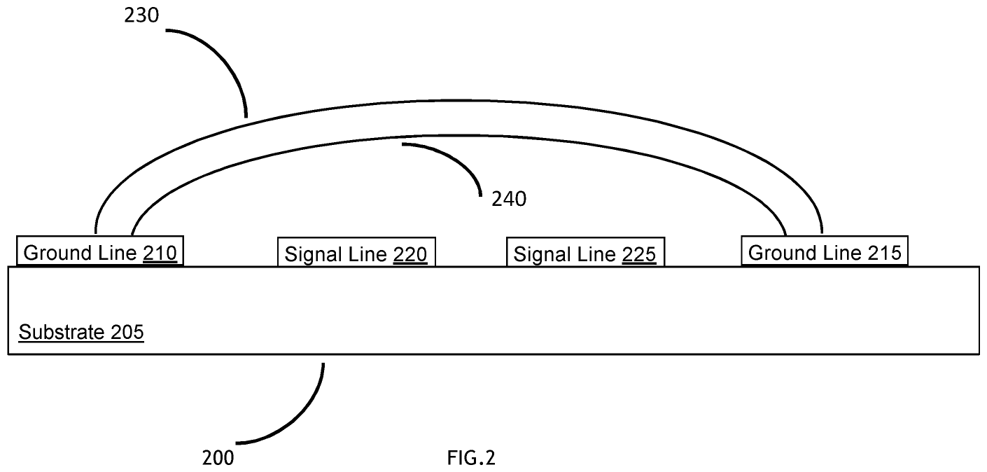

FIG. 2 shows an example of a transmission system with G-S-S-G structure and air bridges connecting ground lines at another cross section

In some embodiments, the system 200 comprises a substrate 205.

In some embodiments, the system 200 comprises a first ground line 210 mounted on the substrate 205, wherein the first ground line 210 is coupled to ground potential.

In some embodiments, the system 200 comprises a second ground line 215 mounted on the substrate 205, wherein the second ground line 215 is coupled to the ground potential, wherein the second ground line 215 is approximately parallel to the first ground line 210, wherein there are a certain distance between the first ground line 210 and the second ground line 215; a number of gold lines 230 and 240 coupled to both the first ground line 210 and the second ground line 215. In some embodiments, gold lines 230 and 240 forms bridges between the first ground line 210 and the second ground line 215.

In some embodiments, the system 200 comprises a pair of signal lines 220 and 225 mounted on the substrate 205, wherein the pair of signal lines 220 and 225 are in-between of the first ground line 210 and the second ground line 215, wherein the pair of signal lines 220 and 225 transmit signals, wherein the bridges formed by the number of gold lines 230 and 240 are configured to remove resonance and improve high frequency performance of signal transmission. In some embodiments, the signals are transmitted via optical means. In some embodiments, the signals are transmitted via electrical means. In some embodiments, the resonance is harmful for the signal transmission system. In some embodiments, frequency of the signal transmission system is configured to reach 35 Ghz. In some embodiments, the resonance occurs more than three times. In some embodiments, only one gold line exists. In some embodiments, more than two gold lines exist. In some embodiments, wherein the gold line 230 and 240 are not connected to signal lines 220 and 225.

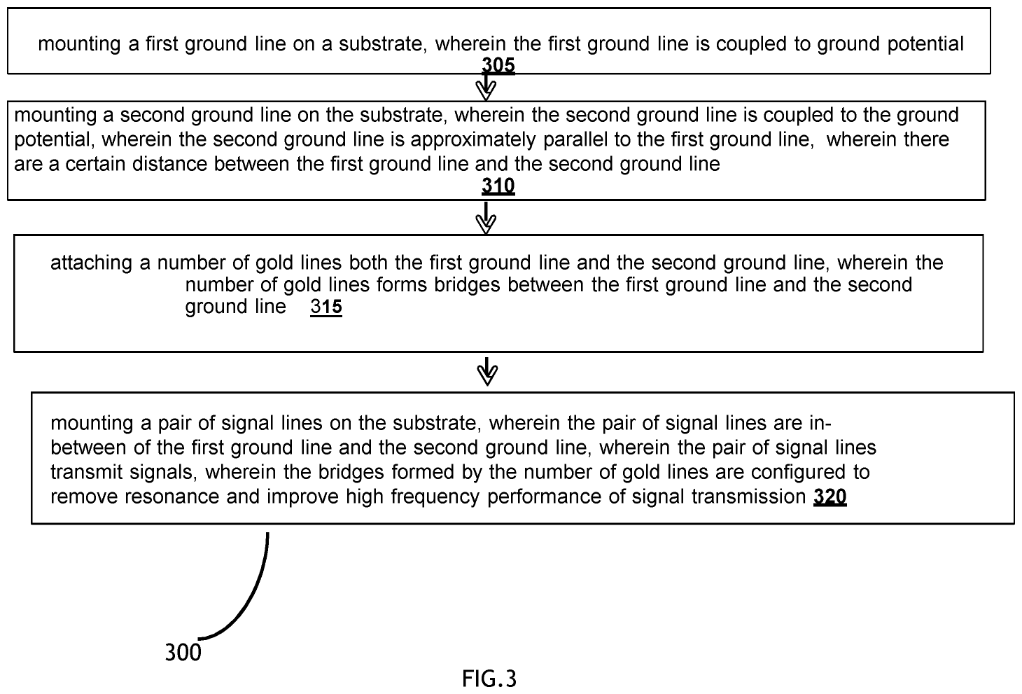

FIG. 3 shows an example of a method with G-S-S-G structure and air bridges.

In some embodiments, a method 300 of transmitting signals comprises a step 305 of mounting a first ground line on a substrate, wherein the first ground line is coupled to ground potential.

In some embodiments, a method 300 of transmitting signals comprises a step 310 of mounting a second ground line on the substrate, wherein the second ground line is coupled to the ground potential, wherein the second ground line is approximately parallel to the first ground line, wherein there are a certain distance between the first ground line and the second ground line.

In some embodiments, a method 300 of transmitting signals comprises a step 315 of attaching a number of gold lines both the first ground line and the second ground line, wherein the number of gold lines forms bridges between the first ground line and the second ground line.

In some embodiments, a method 300 of transmitting signals comprises a step 320 of mounting a pair of signal lines on the substrate, wherein the pair of signal lines are in-between of the first ground line and the second ground line, wherein the pair of signal lines transmit signals, wherein the bridges formed by the number of gold lines are configured to remove resonance and improve high frequency performance of signal transmission.

1. A signal transmission system, comprising:
A substrate;
a first ground line mounted on the substrate, wherein the first ground line is coupled to ground potential;
a second ground line mounted on the substrate, wherein the second ground line is coupled to the ground potential, wherein the second ground line is approximately parallel to the first ground line, wherein there are a certain distance between the first ground line and the second ground line;
a number of gold lines coupled to both the first ground line and the second ground line, wherein the number of gold lines forms bridges between the first ground line and the second ground line; and
a pair of signal lines mounted on the substrate, wherein the pair of signal lines is in-between of the first ground line and the second ground line, wherein the pair of signal lines transmits signals, wherein the bridges formed by the number of gold lines are configured to remove resonance and improve high frequency performance of signal transmission.

2. The signal transmission system of claim 1, wherein the signals are transmitted via electrical means.

3. The signal transmission system of claim 1, wherein the resonance is harmful for the signal transmission system.

4. The signal transmission system of claim 1, wherein frequency of the signal transmission system is configured to reach 35 Ghz.

5. The signal transmission system of claim 1, wherein the resonance occurs at least one time.

6. A method of transmitting signals, comprising:
mounting a first ground line on a substrate, wherein the first ground line is coupled to ground potential;
mounting a second ground line on the substrate, wherein the second ground line is coupled to the ground potential, wherein the second ground line is approximately parallel to the first ground line, wherein there are a certain distance between the first ground line and the second ground line;
attaching a number of gold lines both the first ground line and the second ground line, wherein the number of gold lines forms bridges between the first ground line and the second ground line;
mounting a pair of signal lines on the substrate, wherein the pair of signal lines are in-between of the first ground line and the second ground line, wherein the pair of signal lines transmits signals, wherein the bridges formed by the number of gold lines are configured to remove resonance and improve high frequency performance of signal transmission.

7. The method of transmitting signals of claim 6, wherein the signals are transmitted via electrical means.

8. The method of transmitting signals of claim 7, wherein the resonance is harmful for the signal transmission system.

9. The method of transmitting signals of claim 7, wherein frequency of the signal transmission system is configured to reach 35 Ghz.

10. The method of transmitting signals of claim 7, wherein the resonance occurs at least one time.
